(19) United States
(12) Patent Application Publication
(10) Pub. No.: US 2003/0082842 A1
(43) Pub. Date: May 1, 2003

(54) On-chip temperature sensor formed of MOS tunneling diode

(75) Inventors: Jenn-Gwo Hwu, Taipei (TW); Yen-Hao Shih, Changhua (TW)

Correspondence Address: Haverstock & Owens LLP, Suite 420, 260 Sheridan Avenue, Palo Alto, CA, 94306, US

(73) Assignee: National Taiwan University

(21) Appl. No.: 10/143,214

(22) Filed: May 9, 2002

(30) Foreign Application Priority Data
Oct. 31, 2001 (TW) 090127083

(51) Int. Cl. H01L 21/00; H01L 21/8249; H01L 21/8244; H01L 21/8234; H01L 29/74

(52) U.S. Cl. 438/54; 438/238; 438/234; 438/237; 438/50; 438/30; 438/271; 257/173; 257/444; 257/467

(57) ABSTRACT

The present invention provides an on-chip temperature sensor formed of an MOS tunneling diode. The temperature sensor is formed by processes which are compatible with the below 0.13 μm CMOS technology, so it can be fabricated with MOS devices and integrated into an IC chip. Since the MOS tunneling diode has the characteristic of a diode, a formula showing the exponential relationship between the gate current and the substrate temperature can be obtained when the MOS tunneling diode is biased inversely at a constant voltage. After the current of the MOS tunneling diode is detected, the substrate temperature which represents the real temperature of the IC chip can be figured out.

### FIELD OF THE INVENTION

The present invention relates to a temperature sensor, and more particularly to an on-chip temperature sensor compatible with the CMOS technology.

### BACKGROUND OF THE INVENTION

For the current semiconductor technology, it is at a stage that the smallest line width can be shrunk down to 0.13 μm. An integrated circuit (IC) which is multi-functional and can be operated at a high frequency has been commercialized successfully. However, one incidental problem is the huge heat-generation during operation. Therefore, if the heat in an IC chip cannot be quickly removed, the temperature of the chip will increase unceasingly. This may cause wrong operations and even burnout. Thus, it is an important subject to study an on-chip temperature sensor which enables an IC chip to monitor its die temperature.

Nowadays, the major technology used to detect the temperature of a chip is performed by an external heat-sensitive thermoresistor 10 (as shown in FIG. 1). The method is implemented by adhering the heat-sensitive thermoresistor 10 to a heating chip and detecting the chip temperature via the characteristic—the resistance changes with the temperature. Although such temperature detecting technology is quite easy and convenient, the temperature detected is still not the chip's real temperature, but the temperature of the packaging outside the chip. In fact, the temperature of the packaging may be very different from that of the chip. Beside the thermoresistor, there is another way to precisely detect an IC chip's temperature by a thermodiode sensor. When a constant current goes through a thermodiode, the applied forward bias decreases as the temperature increases. Therefore, the chip temperature can be calculated according to the above-mentioned characteristic. A simple P-N isolating structure can be a thermodiode.

During studying ultra-thin gate oxides, we found an MOS capacitor with an ultra-thin oxide behaved like a thermodiode. It is named “MOS tunneling diode”. Therefore, a new type of temperature sensor is found. For convenience, the MOS tunneling diode is also called “MOS tunneling temperature sensor” due to its temperature-detection function.

### SUMMARY OF THE INVENTION

It is an object of the present invention to provide a method for forming an on-chip temperature sensor by using an MOS tunneling diode.

It is another object of the present invention to provide a temperature sensor formed of an MOS tunneling diode which can be integrated into an IC chip to detect the chip's temperature.

In accordance with an aspect of the present invention, the method for forming a temperature sensor comprises steps of: forming plural trenches on a semiconductor substrate; forming a first oxide layer in the trenches; forming an ultra-thin gate oxide layer on the semiconductor substrate; forming a gate electrode on a portion of the gate oxide layer and defining an MOS structure having the characteristic of a diode; forming a second oxide layer on the gate oxide layer and the gate electrode; and removing a portion of the second oxide layer to expose the gate electrode for setting conducting wires of the temperature sensor thereafter.

Preferably, the semiconductor substrate is a P-type silicon substrate.

Preferably, the ultra-thin gate oxide layer is thinner than 3 nm.

According to the method for forming the temperature sensor described above, the step of forming the gate electrode further comprises steps of: forming a metal layer on the gate oxide layer; and removing a portion of the metal layer and exposing the gate oxide layer for defining the gate electrode.

Preferably, the metal layer is made of a metal.

Preferably, the metal is formed by one of sputtering and thermal evaporation.

Preferably, the metal layer is made of n⁺ polysilicon.

Preferably, the steps of removing a portion of the metal layer and exposing the gate oxide layer for defining the gate electrode is performed by a first photolithography and etching procedure.

Preferably, the step of removing a portion of the second oxide layer to expose the gate electrode is performed by a second photolithography and etching procedure.

According to the method for forming the MOS tunneling temperature sensor described above, the method further comprises a step of an annealing procedure to reduce the density of interface traps between the gate oxide layer and the semiconductor substrate.

In accordance with another aspect of the present invention, an on-chip temperature sensor comprises a semiconductor substrate, an ultra-thin gate oxide layer formed on the semiconductor substrate and a gate electrode formed on the gate oxide layer.

According to the on-chip temperature sensor described above, the semiconductor substrate further comprises plural trenches and a first oxide layer filling the trenches.

Preferably, the semiconductor substrate is a P-type silicon substrate.

Preferably, the ultra-thin gate oxide layer is thinner than 3 nm.

According to the on-chip temperature sensor described above, the temperature sensor further comprises a second oxide layer formed on the gate oxide layer and having a contact hole for exposing the gate electrode.

Preferably, the gate electrode has a material being one of metal and n+polysilicon.

Preferably, the metal is aluminum.

The above objects and advantages of the present invention will become more readily apparent to those ordinarily skilled in the art after reviewing the following detailed descriptions and accompanying drawings, in which:

### BRIEF DESCRIPTION OF THE DRAWINGS

FIG. 1 is a temperature sensor using an external heat-sensitive resist (thermoresistor) for detecting temperature of a chip according to the prior art;

FIGS. 2A˜2D are cross-sectional views illustrating the fabrication process of an MOS tunneling temperature sensor according to a preferred embodiment of the present invention;

FIG. 3 is a schematic view showing the MOS tunneling temperature sensor biased inversely according to the present invention;

FIG. 4 shows the energy band diagram of the MOS tunneling temperature sensor biased inversely according to the present invention;

FIG. 5 shows the characteristic curve correlating the gate current and the substrate temperature when an practical MOS tunneling temperature sensor is biased inversely at 1.8V according to the present invention; and

FIG. 6 shows the experimental data illustrating the reproducibility of the temperature detecting methodology according to the present invention.

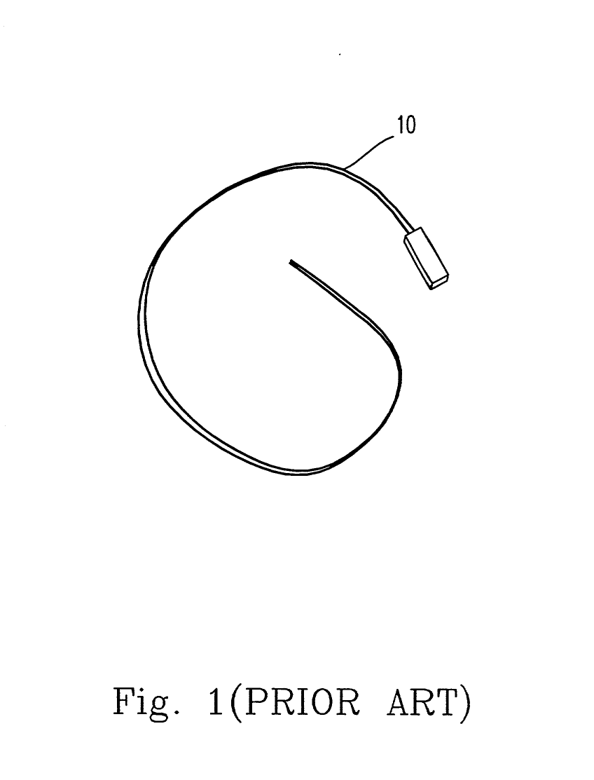

### DETAILED DESCRIPTION OF THE PREFERRED EMBODIMENT

As known by general VLSI technicians, an MOS capacitor is a basic structure of MOS transistors. Therefore, in the present invention, the process for forming an MOS tunneling temperature sensor which is basically an MOS capacitor is compatible with the 0.13 μm CMOS technology, and can be further integrated into CMOS chips.

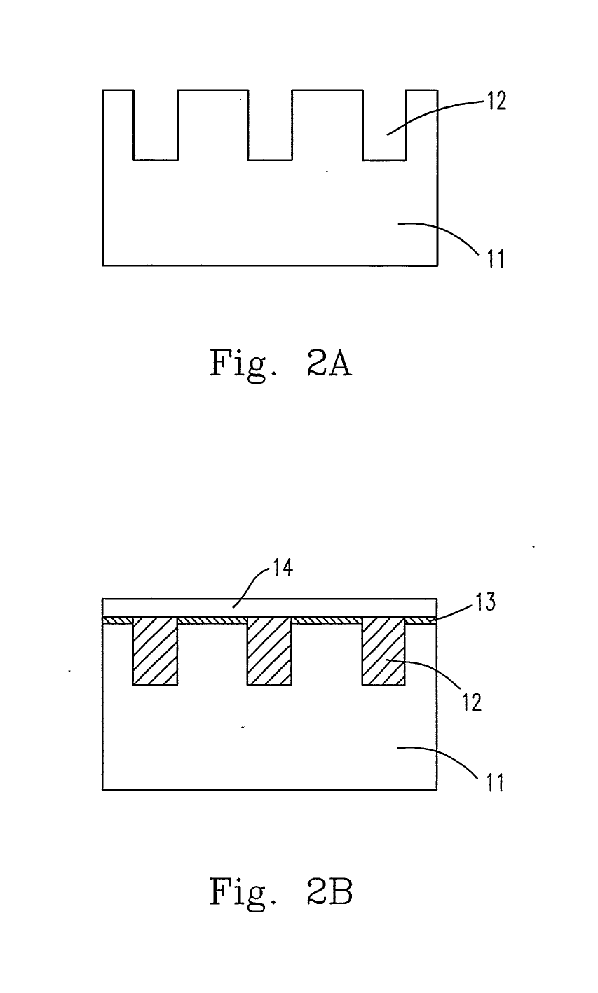

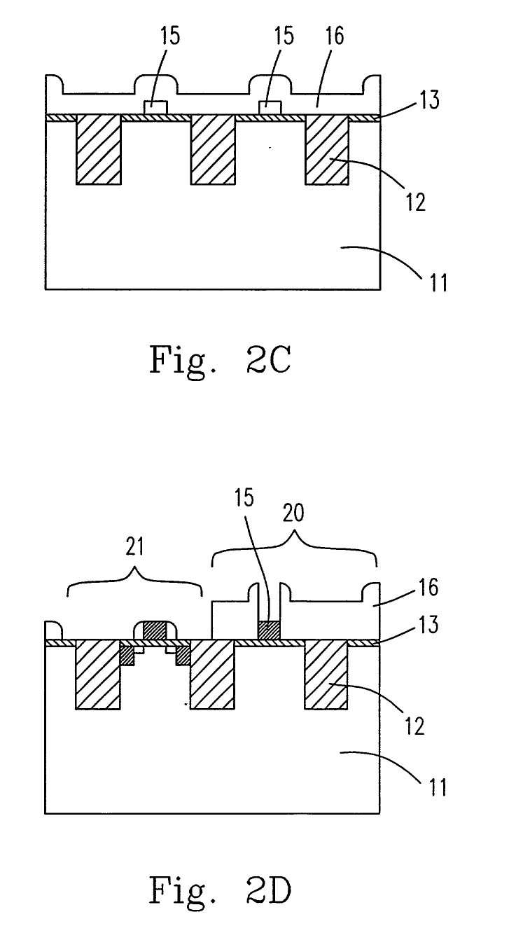

Please refer to FIG. 2A. First, a semiconductor substrate 11, such as a P-type silicon substrate, is provided and plural trenches 12 are formed thereon. As shown in FIG. 2B, a first oxide layer fills the trenches 12, which defines isolation areas of the semiconductor substrate. Then an ultra-thin gate oxide layer 13 having a thickness about 2.1 nm (generally, smaller than 3 nm) is formed on the semiconductor substrate 11. A gate metal layer 14, which is preferably an aluminum layer formed by sputtering/evaporation or an n⁺ polysilicon layer formed by low pressure chemical vapor deposition (LPVCD), is deposited on the gate oxide layer 13.

As shown in FIG. 2C, a first photolithography and etching procedure is subsequently performed to define the gate electrodes 15, and also to define the active region of the temperature sensor 20 simultaneously (as shown in FIG. 2D). A second oxide layer 16 is then formed on the gate oxide layer 13 and the gate electrode 15. Please refer to FIG. 2D, a second photolithography and etching procedure is performed to form a contact hole for exposing the gate electrode 15, which is helpful for setting conducting wires thereafter to conduct the temperature-dependent gate current to the current sensing circuit. The other region 21 is used to perform the succeeding process for MOS devices, such as procedures of defining drain/source regions, and then to form integrated circuits. Finally, a postmetallization annealing (PMA) procedure is performed to reduce the density of interface traps between the gate electrode 15 and the gate oxide layer 13, and to increase the sensitivity of temperature.

The method to detect temperature of an IC chip by using the MOS tunneling temperature sensor will be described in detail as follows. According to the roadmap of the present semiconductor technology, a gate oxide layer 13 of an MOS transistor formed by the 0.25 μm technology has a thickness of 5 nm, while a gate oxide layer 13 of an MOS transistor formed by the 0.13 μm technology has a thickness about 2.4 nm. When a gate oxide layer is thinner than 3 nm, the direct tunneling effect will occur, which reduces the insulating effect of the gate oxide layer 13 and generates a tunneling current.

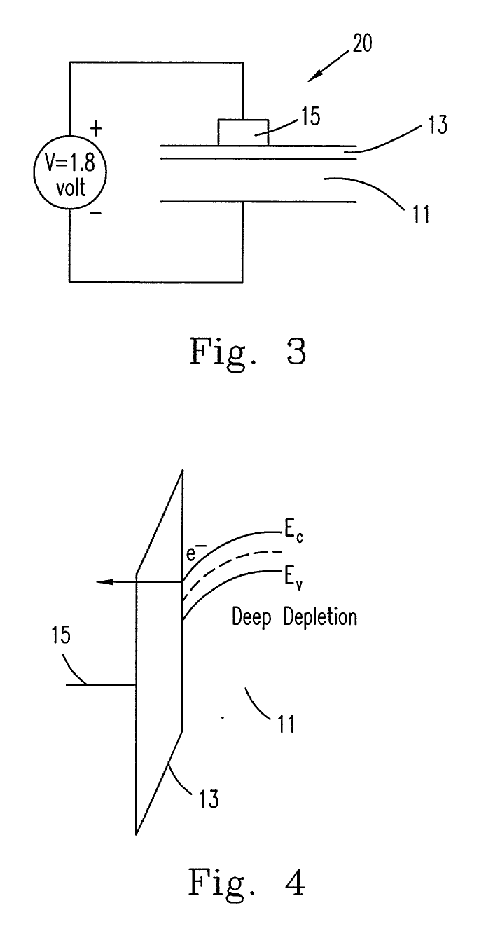

FIG. 3 shows the MOS structure 20 used as a temperature sensor in the present invention being biased inversely. As shown in FIG. 3, when the insulating effect of the gate oxide layer 13 of the MOS structure 20 is weak and the MOS capacitor is biased inversely, the capacitor enters deep depletion, as shown in FIG. 4 of the energy band diagram. As the absolute value of the inverse bias voltage increases, the current will reach a saturation state and does not increase further. On the contrary, if the MOS capacitor is biased forwardly, the current will increase steeply with the absolute value of the gate voltage. Therefore, the MOS structure 20 of the present invention has the characteristic of a diode and is called as an MOS tunneling diode.

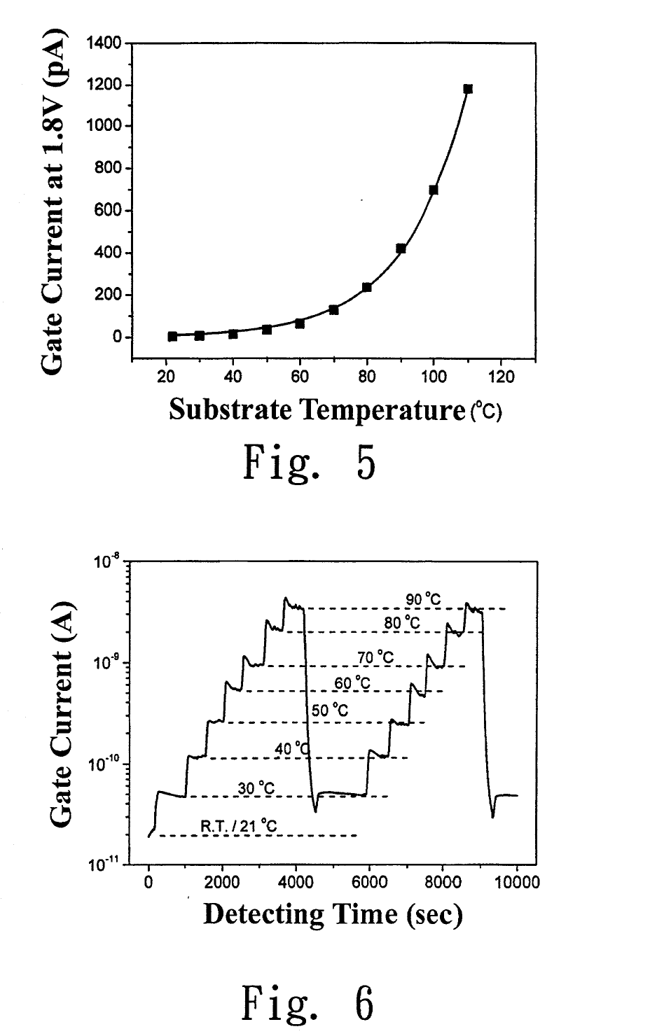

In a preferred embodiment of the present invention, the thickness of the ultra-thin gate oxide layer of the MOS tunneling diode is 2.1 nm. The area of the MOS tunneling diode is 2.25×10⁻⁴ cm², and the operating voltage is 1.8V. Under such operating condition, the correlation between the gate current and the substrate temperature can be found, and the characteristic curve is shown in FIG. 5. When the substrate temperature is 22° C., the gate current is 2.83×10⁻¹²A. When the substrate temperature is 40° C., the gate current is 1.45×10⁻¹¹A. When the substrate temperature is 90° C., the gate current is 4.22×10⁻¹¹A. An equation derived from the curve of gate current—substrate temperature in FIG. 5 clearly defines the relation between the gate current and the substrate temperature. The equation showing the exponential relationship between the gate current and the substrate temperature is represented as follows:

$${I}_{1.8 V} = 9.742 \times {10}^{- 13} \times exp ( \frac{T}{14.93} )$$

In the formula, I_{1.8V} represents the current of the diode biased inversely at 1.8V whose unit is ampere (amp), and T represents the substrate temperature whose unit is centigrade (° C.). After the current of the MOS tunneling diode is detected by a precise current equipment, the substrate temperature can be calculated by introducing the detected current into the above formula. Therefore, to cooperate with a precise ampere meter, the temperature sensor of the MOS tunneling diode in the present invention can precisely detect the substrate temperature which represents the real temperature of an IC chip.

FIG. 6 shows the experimental data illustrating the reproducibility of the temperature detecting technology in the present invention. First, the substrate is heated up by a heater, and the gate current of the temperature sensor which is biased inversely at 1.8V is detected simultaneously. The heating program is to heat the substrate from room temperature to 30° C. After the substrate temperature steadies for a while, the substrate is heated again up to 40 ° C. and steadies. The above-mentioned heating steps are repeated until the substrate temperature is 90° C. and in a steady state. After that, the substrate is cooled by a water cooling system down to 25° C., and another gradually heating program starts again. It is found from the experimental data shown in FIG. 6 that in the prior and the posterior heating programs, the inverse bias currents of the MOS tunneling temperature sensor of the present invention at the same temperature are consistent. It shows that the MOS tunneling temperature sensor in the present invention can be manipulated stably and repeatedly.

The technology for detecting temperature of an IC chip provided by the present invention is to use an MOS tunneling diode. When the temperature sensor is biased inversely at a constant voltage, there is an exponential fitting correlation between the gate current and the substrate temperature. Therefore, the substrate temperature can be calculated by means of the detected gate current. Moreover, the MOS tunneling diode can be formed together with MOS elements in the below 0.13 um CMOS technology. Hence there is no need to change the manufacturing parameters and to add extra equipments, which substantially reduces the manufacturing cost and the difficulty of circuit design. Obviously, the present invention provides an on-chip temperature sensor formed by the same process of forming IC elements, which successfully overcomes the difficulties and the disadvantages encountered in thermoresistors, and protects IC devices from being overheated, and increases reliability of the circuit elements.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method for forming a temperature sensor, comprising steps of:
forming plural trenches on a semiconductor substrate;
forming a first oxide layer in said trenches;
forming an ultra-thin gate oxide layer on said semiconductor substrate;
forming a gate electrode on a portion of said gate oxide layer and defining an MOS structure having the characteristic of a diode;
forming a second oxide layer on said gate oxide layer and said gate electrode; and
removing a portion of said second oxide layer to expose said gate electrode for setting conducting wires of said temperature sensor thereafter.

2. The method according to claim 1 wherein said semiconductor substrate is a P-type silicon substrate.

3. The method according to claim 1 wherein said ultra-thin gate oxide layer is thinner than 3 nm.

4. The method according to claim 1 wherein the step of forming said gate electrode further comprises steps of:
forming a metal layer on said gate oxide layer; and
removing a portion of said metal layer and exposing said gate oxide layer for defining said gate electrode.

5. The method according to claim 4 wherein said metal layer is made of a metal.

6. The method according to claim 5 wherein said metal is formed by one of sputtering and evaporation.

7. The method according to claim 4 wherein said metal layer is made of n⁺ polysilicon.

8. The method according to claim 4 wherein the steps of removing a portion of said metal layer and exposing said gate oxide layer for defining said gate electrode is performed by a first photolithography and etching procedure.

9. The method according to claim 1 wherein the step of removing a portion of said second oxide layer to expose said gate electrode is performed by a second photolithography and etching procedure.

10. The method according to claim 1 further comprising a step of an annealing procedure to reduce the density of interface traps between said gate oxide layer and said semiconductor substrate.

11. An on-chip temperature sensor comprising:
a semiconductor substrate;
an ultra-thin gate oxide layer formed on said semiconductor substrate; and
a gate electrode formed on said gate oxide layer.

12. The temperature sensor according to claim 11 wherein said semiconductor substrate further comprises plural trenches and a first oxide layer formed in said trenches.

13. The temperature sensor according to claim 11 wherein said semiconductor substrate is a P-type silicon substrate.

14. The temperature sensor according to claim 11 wherein a thickness of said ultra-thin gate oxide layer is thinner than 3 nm.

15. The temperature sensor according to claim 11 further comprising a second oxide layer formed on said gate oxide layer and having a contact hole for exposing said gate electrode.

16. The temperature sensor according to claim 11 wherein said gate electrode has a material being one of metal and n+polysilicon.

17. The temperature sensor according to claim 16 wherein said metal is aluminum.
